(19) United States
(12) Patent Application Publication
(10) Pub. No.: US 2025/0126718 A1
(43) Pub. Date: Apr. 17, 2025

(54) PRINTED CIRCUIT BOARD

(71) Applicant: SAMSUNG ELECTRO-MECHANICS CO., LTD., Suwon-si (KR)

(72) Inventors: Jae Ho SHIN, Suwon-si (KR); Jae Woong CHOI, Suwon-si (KR)

(73) Assignee: SAMSUNG ELECTRO-MECHANICS CO., LTD., Suwon-si (KR)

(21) Appl. No.: 18/741,290

(22) Filed: Jun. 12, 2024

(30) Foreign Application Priority Data
Oct. 13, 2023 (KR) 10-2023-0136405
Nov. 15, 2023 (KR) 10-2023-0157808

(51) Int. Cl. H05K 1/18; H05K 1/03; H05K 1/11; H05K 1/14; H05K 3/38

(52) U.S. Cl. CPC H05K 1/185; H05K 1/0313; H05K 1/115; H05K 1/144; H05K 3/388; H05K 2201/032; H05K 2201/0341; H05K 2201/042; H05K 2201/09527; H05K 2201/096; H05K 2201/10098

(57) ABSTRACT

A printed circuit board includes a first substrate including a first antenna pattern; a second substrate disposed on a first substrate and including a second antenna pattern; a metal layer disposed between the first and second substrates; and a bonding layer disposed between the first and second substrates. At least one of the first and second substrates has a cavity having at least a portion disposed between the first and second antenna patterns, each of the first and second substrates includes an organic material, and the bonding layer includes an inorganic material.

### CROSS-REFERENCE TO RELATED APPLICATIONS

This application claims benefit of priority to Korean Patent Application No. 10-2023-0157808 filed on Nov. 15, 2023 and Korean Patent Application No. 10-2023-0136405 filed on Oct. 13, 2023 in the Korean Intellectual Property Office, the disclosures of which are incorporated herein by reference in their entirety.

### TECHNICAL FIELD

The present disclosure relates to a printed circuit board, for example, an antenna substrate.

### BACKGROUND

With the commercialization of 5G and a rapid increase in data usage, performance of an antenna for wireless communications has become increasingly important. In particular, a phased array antenna has been widely used in various wireless communication environments, such as a battlefield, and a base station based on a mobile device including a smartphone. In the case of phased array antennas, a small-sized antenna may be designed in the form of a patch and may be arranged in parallel or series, may have the advantage of being able to transmit and receive data faster in a desired direction, and may also be miniaturized if desired, such that, with the introduction of 5G, the antenna has been adopted in a mobile device. As performance of a patch antenna may be determined by a shape, a structure, and material properties of an antenna, research has been actively conducted thereon in related academia and companies.

### SUMMARY

An aspect of the present disclosure is to provide a printed circuit board including an antenna pattern and having an air gap structure.

An aspect of the present disclosure is to provide a printed circuit board which may increase antenna performance.

An aspect of the present disclosure is to form a first substrate including a first antenna pattern and a second substrate including a second antenna pattern, respectively, a cavity in at least one of first and second substrates, and thereafter, to bonding first and second substrates using hybrid metal bonding.

For example, according to an example embodiment, a printed circuit board includes a first substrate including a first antenna pattern; a second substrate disposed on a first substrate and including a second antenna pattern; a metal layer disposed between the first and second substrates; and a bonding layer disposed between the first and second substrates. At least one of the first and second substrates has a cavity having at least a portion disposed between the first and second antenna patterns, each of the first and second substrates includes an organic material, and the bonding layer includes an inorganic material.

For example, according to an example embodiment, a printed circuit board includes a first substrate including a first antenna pattern; a second substrate disposed on the first substrate and including a second antenna pattern; a metal layer disposed between the first and second substrates; and a bonding layer disposed between the first and second substrates. At least one of the first and second substrates has a cavity having at least a portion disposed between the first and second antenna patterns, and at least a portion of a side surface of the metal layer has a step difference.

For example, according to an example embodiment, a method of manufacturing a printed circuit board includes preparing a first substrate including a first antenna pattern and including a first metal layer formed on an outermost side thereof; forming a first inorganic insulating film covering at least a portion of the first metal layer on the outermost side of the first substrate; preparing a second substrate including a second antenna pattern and including a second metal layer formed on an outermost side thereof; forming a second inorganic insulating film covering at least a portion of the second metal layer on the outermost side of the second substrate; forming a cavity in at least one of the first and second substrates; and bonding the first and second substrates to each other such that the first and second inorganic insulating films are bonded to each other and the first and second metal layers are bonded to each other. Each of the first and second substrates includes an organic material.

For example, according to an example embodiment, a printed circuit board includes a first substrate including a first antenna pattern; a second substrate disposed on a first substrate and including a second antenna pattern; a metal layer disposed between the first and second substrates; and a bonding layer disposed between the first and second substrates and covering side surfaces of the metal layer. At least one of the first and second substrates has a cavity having at least a portion disposed between the first and second antenna patterns. A thickness of the bonding layer between the first substrate and the cavity is smaller than a thickness of the bonding layer between the first and second substrates.

For example, according to an example embodiment, a printed circuit board includes a first substrate including a plurality of first insulating layers, a plurality of first wiring layers disposed on or in the plurality of first insulating layers, one of the plurality of first wiring layers including a first antenna pattern; a second substrate disposed on the first substrate and including a plurality of second insulating layers, a plurality of second wiring layers disposed on or in the plurality of second insulating layers, respectively, and a plurality of second via layers penetrating at least one of the plurality of second insulating layers, respectively, one of the plurality of second insulating layers including a second antenna pattern; a metal layer disposed between the first and second substrates; and a bonding layer disposed between the first and second substrates and covering side surfaces of the metal layer. At least one of the first and second substrates has a cavity having at least a portion disposed between the first and second antenna patterns. A via layer among the plurality of first via layers which is connected to the metal layer and a via layer of the plurality of second via layers which is connected to the metal layer are tapered in opposite directions.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating an example of an electronic device system;

FIG. 2 is a plan diagram illustrating an example of an electronic device;

FIG. 3 is a cross-sectional diagram illustrating an example of a printed circuit board;

FIG. 4 is a cross-sectional diagram illustrating another example of a printed circuit board;

FIGS. 5A to 5D are enlarged cross-sectional diagram illustrating various examples of hybrid metal bonding;

FIGS. 6A and 6B are enlarged cross-sectional diagram illustrating various examples of a boundary surface in intermetallic bonding;

FIGS. 7A to 7E are plan diagrams illustrating various examples of a cavity;

FIG. 8 is a diagram illustrating an example of a method of manufacturing a printed circuit board;

FIGS. 9A to 9C are cross-sectional diagrams illustrating an example of processes of manufacturing a first substrate portion;

FIGS. 10A to 10E are cross-sectional diagrams illustrating an example of processes of manufacturing a second substrate portion;

FIG. 11 is a cross-sectional diagram illustrating an example of bonding of first and second substrate portions;

FIG. 12 is a cross-sectional diagram illustrating processes of hybrid metal bonding according to an example embodiment;

FIG. 13 is a graph indicating a temperature cycle of hybrid metal bonding according to an example embodiment;

FIG. 14 is cross-sectional diagrams illustrating another example of hybrid metal bonding according to an example embodiment; and

FIG. 15 is cross-sectional diagrams illustrating another example of hybrid metal bonding according to an example embodiment.

### DETAILED DESCRIPTION

Hereinafter, embodiments of the present disclosure will be described as follows with reference to the attached drawings.

### Electronic Device

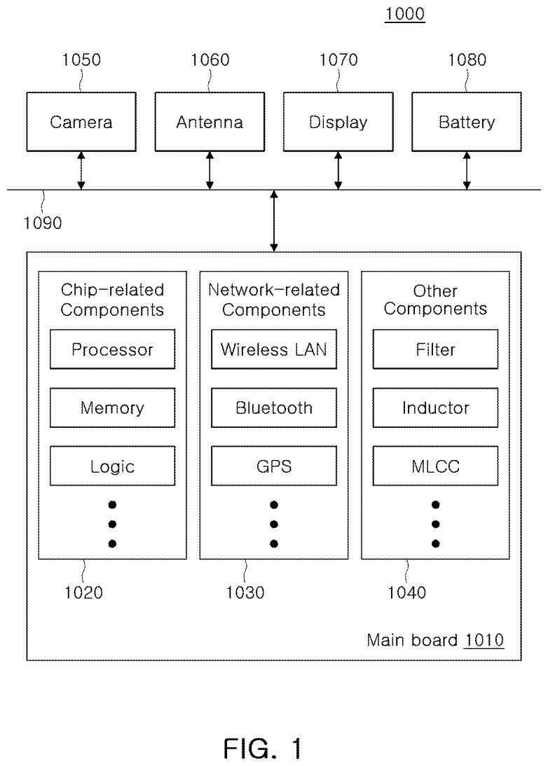

FIG. 1 is a block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

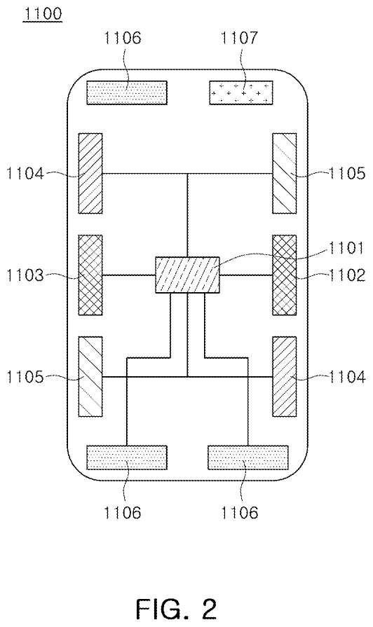

FIG. 2 is a plan diagram illustrating an example of an electronic device.

Referring to FIG. 2, an electronic device may be a smartphone 1100. A modem 1101, a Rigid printed circuit board, a flexible printed circuit board and/or various types of antenna substrates or modules 1102, 1103, 1104, 1105, and 1106 connected to the modem 1101 through a rigid-flexible printed circuit board may be disposed in the smartphone 1100. If desired, a WiFi substrate or a module 1107 may also be disposed. The antenna substrate or the module 1102, 1103, 1104, 1105, and 1106 may include an antenna substrate or modules 1102, 1103, 1104, and 1105 in various frequency bands for 5G mobile communication, for example, an n antenna substrate or module 1102 for 3.5 GHz band frequency, an antenna substrate or module 1103 for 5 GHz band frequency, an antenna substrate or module 1104 for 28 GHz band frequency, and an antenna substrate or module 1105 for 39 GHz band frequency, and another 4G antenna substrate or module 1106 may also be included, but an example embodiment thereof is not limited thereto. The electronic device may not be necessarily limited to the smartphone 1100, and may be implemented as another electronic device as described above.

### Printed Circuit Board

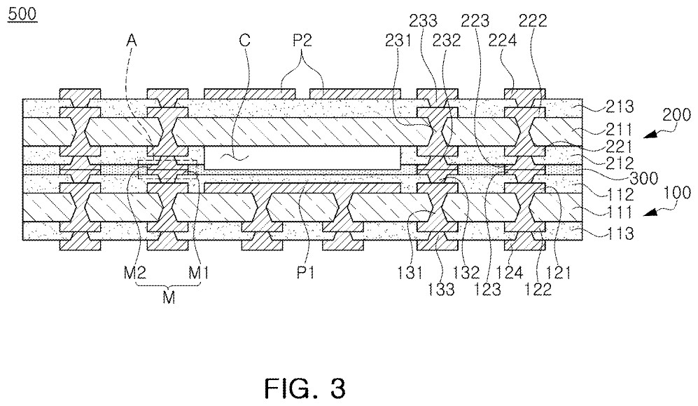

FIG. 3 is a cross-sectional diagram illustrating an example of a printed circuit board.

Referring to the drawing, a printed circuit board 500 according to an example may include a first substrate 100 including a first antenna pattern P1 and a first metal layer M1 disposed on an upper side thereof, a second substrate 200 disposed on the first substrate 100, including a second antenna pattern P2, and including a second metal layer M2 disposed on a lower side thereof, and a bonding layer 300 disposed between the first and second substrates 100 and 200 and burying at least a portion of each of the first and second metal layers M1 and M2. Each of the first and second substrates 100 and 200 may include an organic material. The bonding layer 300 may include an inorganic material. At least one of the first and second substrates 100 and 200 may have a cavity C. For example, the second substrate 200 may have the cavity C having at least a portion disposed between the first and second antenna patterns P1 and P2. The first metal layer M1 and the second metal layer M2 may be bonded to each other using hybrid metal bonding with the bonding layer 300. For example, an upper surface of the first metal layer M1 and a lower surface of the second metal layer M2 may be bonded to each other. The first and second metal layers M1 and M2 may be bonded to each other and integrated into the metal layer M. A boundary between the first and second metal layers M1 and M2 may or may not be distinct. The bonding layer 300 may be disposed adjacent to the metal layer M.

In a general patch antenna substrate or module structure, a size and performance of an antenna may have a close correlation with a dielectric constant of a material forming the antenna. In this case, since the antenna substrate or module may generally be manufactured through a process of manufacturing a printed circuit board, a dielectric constant of a material may ultimately be limited to a dielectric constant of a material of the printed circuit board. Generally, when a dielectric constant is low, antenna performance may improve, such that a material having a low dielectric constant may be often preferred, but there may be the issue of an increase in size of the antenna, a low-K material may not be necessarily used. However, because a size of the antenna may be reduced depending on a design and structural properties of a patch, consequently, it may be desirable to use a low-K material to improve performance of the antenna. Accordingly, it may be necessary to improve performance of the antenna by providing a low dielectric constant while using the same general material used for a printed circuit board.

Also, in a patch antenna structure, generally, when a dielectric constant of a substrate material is relatively high, a size of antenna may be reduced, and in this case, a bandwidth of the antenna may also be reduced. When a dielectric constant of the substrate is low, the size of the antenna may be increased and the bandwidth of the antenna may be increased. Accordingly, in the case of a patch antenna, it may be necessary to find an optimal point at which a bandwidth may increase while reducing a size. For example, a size may be reduced by variously modifying a patch design using a low-K material for the substrate.

A dielectric constant of a low-material of the substrate may be higher than a dielectric constant of air. For example, the dielectric constant of the material may be represented as a number proportional to 1, which is a dielectric constant in a vacuum state, and accordingly, the dielectric constant may be close to 1 but may not be 1, and air may be a substance closest to 1. Accordingly, when manufacturing an antenna substrate or module, when an air gap structure having an area corresponding to a patch antenna is manufactured, a dielectric constant may be lowered to be close to 1 in a portion in which an air gap is formed regardless of an insulating material of the substrate, and accordingly, the highest bandwidth may be implemented.

From this perspective, in the printed circuit board 500 according to an example, the first antenna pattern P1 and the second antenna pattern P2 may include a coupling pattern and a patch pattern, respectively, and the cavity C formed on the second substrate 200 may be disposed between the patch pattern and the coupling pattern such that at least a portion thereof may be filled with air. Accordingly, when the first and second substrates 100 and 200 are bonded to each other by hybrid metal bonding, an antenna substrate or a module structure having an air gap structure may be provided, and accordingly, excellent antenna properties may be implemented. In particular, by freely forming the cavity C in response to a shape or a size of the first and second antenna patterns P1 and P2, the degree of freedom in designing the air gap may be increased and antenna performance may be increased. Also, since the first and second substrates 100 and 200 are bonded to each other through hybrid metal bonding by the bonding layer 300 and the metal layer M, an overall thickness of the substrate may be reduced, bonding reliability may be improved, and since it may not be necessary to form another bonding pad, design freedom may be increased.

Hereinafter, components of the printed circuit board 500 according to an example will be described in greater detail with reference to the drawings.

The first substrate 100 may be configured as a multilayer printed circuit board. For example, the first substrate 100 may include a plurality of first insulating layers 111, 112, and 113, a plurality of first wiring layers 121, 122, 123, and 124 disposed on or in the plurality of first insulating layers 111, 112, and 113, and a plurality of first via layers 131, 132, and 133 penetrating at least one of the plurality of first insulating layers 111, 112, and 113, respectively. At least one of the plurality of first insulating layers 111, 112, and 113 may include an organic material. At least one of the plurality of first wiring layers 121, 122, 123, and 124 may include the first antenna pattern P1. Each of the plurality of first wiring layers 121, 122, 123, and 124 may include a feeding pattern. Each of the plurality of first via layers 131, 132, and 133 may include a feeding via. Among the plurality of first wiring layers 121, 122, 123, and 124, a wiring layer 123 disposed on an uppermost side may include a first metal layer M1. The first substrate 100 may be configured as a core type multilayer substrate including a 1-1 insulating layer 111 as a core layer, or may also be configured as a coreless type multilayer substrate not including a core layer.

Each of the plurality of first insulating layers 111, 112, and 113 may be configured as an organic insulating layer. For example, the plurality of first insulating layers 111, 112, and 113 may include an organic insulating material. The organic insulating material may include a thermosetting resin such as an epoxy resin, a thermoplastic resin such as polyimide, or a material including an inorganic filler, an organic filler, and/or glass fiber (glass cloth, glass fabric) along with resin. For example, the organic insulating material may be a non-photosensitive insulating material such as copper clad laminate (CCL), Ajinomoto build-up film (ABF), or prepreg (PPG), but an example embodiment example thereof is not limited thereto, and other polymer materials may be used. For example, thermoplastic resin such as polyimide (PI), liquid crystal polymer (LCP), polytetrafluoroethylene (PTFE), polyphenylene sulfide (PPS), polyphenylene ether (PPE), polyphenylene ether (PPE), and modified polyester, or thermosetting resin such as mead (PI) and modified epoxy may be used. If desired, at least one of the plurality of first insulating layers 111, 112, and 113, for example, the 1-1 insulating layer 111 may include other types of insulating material other than an organic insulating material such as glass and ceramic. Even in this case, the other 1-2 and 1-3 insulating layers 112 and 113 may include an organic insulating material. The 1-1 insulating layer 111 may be configured as a core layer, and the 1-2 and 1-3 insulating layers 112 and 113 may be build-up layers. The 1-1 insulating layer 111 may have a thickness greater than those of the 1-2 and 1-3 insulating layers 112 and 113.

Each of the plurality of first wiring layers 121, 122, 123, and 124 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an example embodiment thereof is not limited thereto. Each of the plurality of first wiring layers 121, 122, 123, and 124 may perform various functions depending on a design. For example, a signal pattern, a power pattern, and a ground may be included. Each of the patterns may have various forms such as a line form, a plain form, and a pad form. The plurality of first wiring layers 121, 122, 123, and 124 may include a seed layer and a plating layer formed on the seed layer, respectively. The seed layer may be an electroless plating layer (or chemical copper) and/or a sputtering layer, and the plating layer may be an electrolytic plating layer (or electrical copper), but an example embodiment thereof is not limited thereto. The 1-1 and 1-2 wiring layers 121 and 122 may be disposed on upper and lower surfaces of the 1-1 insulating layer 111, respectively, and the 1-3 and 1-4 wiring layers may be disposed on an upper surface of the 1-2 insulating layer 112 and a lower surface of the 1-3 insulating layer 113, respectively, but an example embodiment thereof is not limited thereto.

The first antenna pattern PI may include a coupling pattern. The coupling pattern may be disposed on a lower side of an air gap and a patch pattern. For example, the coupling pattern may overlap at least portions of the air gap and the patch pattern on a plane. By electromagnetic coupling between the coupling pattern and the patch pattern, an additional resonant frequency close to an intrinsic resonant frequency may be obtained, and accordingly, a wider bandwidth may be obtained.

The first metal layer M1 may include various types of conductor patterns. For example, the first metal layer M1 may include a conductor pattern such as a line, a pad, and a plane. The first metal layer M1 may be disposed in a position substantially corresponding to the second metal layer M2, and the conductor pattern of the first metal layer M1 may have a shape substantially corresponding to the conductor pattern of the second metal layer M2. The 1-3 wiring layer 123 including the first metal layer M1 may be planarized as in a process described later, and may thus have a thickness smaller than thicknesses of the other 1-1, 1-2, and 1-4 wiring layers 121, 122, and 124. For example, the first metal layer M1 may have a thickness smaller than that of the first antenna pattern P1.

Each of the plurality of first via layers 131, 132, and 133 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an example embodiment thereof is not limited thereto. Each of the plurality of first via layers 131, 132, and 133 may include a filled via filling a via hole, or may also include a conformal via disposed along a wall surface of the via hole. The plurality of first via layers 131, 132, and 133 may perform various functions depending on a design. For example, a ground via, a power via, and a signal vias may be included. The plurality of first via layers 131, 132, and 133 may include an electroless plating layer (or chemical copper) and an electrolytic plating layer (or electric copper). A sputtering layer may be included instead of an electroless plating layer (or chemical copper), or, if desired, both may be included. The 1-1 via layer 131 may have an hourglass or a pillar shape in a cross-section. The 1-2 and 1-3 via layers 132 and 133 may have a tapered shape in opposite directions in a cross-section.

The second substrate 200 may be configured as a multilayer printed circuit board. For example, the second substrate 200 may have a plurality of second insulating layers 211, 212, and 213, a plurality of second wiring layers 221, 222, 223, and 224 disposed on or in the plurality of second insulating layers 211, 212, and 213, respectively, and the plurality of second via layers 231, 232, and 233 penetrating at least one of the plurality of second insulating layers 211, 212, and 213, respectively. At least one of the plurality of second insulating layers 211, 212, and 213 may include an organic material. At least one of plurality of second wiring layers 221, 222, 223, and 224 may include a second antenna pattern P2. Each of the plurality of second wiring layers 221, 222, 223, and 224 may include a feeding pattern. Each of the plurality of second via layers 231, 232, and 233 may include a feeding via. Among the plurality of second wiring layers 221, 222, 223, and 224, a wiring layer 223 disposed on a lowermost side may include a second metal layer M2. The second substrate 200 may be configured as a core type multilayer substrate including the 2-1 insulating layer 211 as a core layer, or may also be configured as a coreless type multilayer substrate not including a core layer.

Each of the plurality of second insulating layers 211, 212, and 213 may be an organic insulating layer. For example, the plurality of second insulating layers 211, 212, and 213 may include an organic insulating material. The organic insulating material may include a thermosetting resin such as an epoxy resin, a thermoplastic resin such as polyimide, or a material including an inorganic filler, an organic filler, and/or glass fiber (glass cloth, glass fabric) along with resin. For example, the organic insulating material may be a non-photosensitive insulating material such as copper clad laminate (CCL), Ajinomoto build-up film (ABF), or prepreg (PPG), but an example embodiment example thereof is not limited thereto, and other polymer materials may be used. For example, thermoplastic resin such as polyimide (PI), liquid crystal polymer (LCP), polytetrafluoroethylene (PTFE), polyphenylene sulfide (PPS), polyphenylene ether (PPE), polyphenylene ether (PPE), and modified polyester, or thermosetting resin such as mead (PI) and modified epoxy may be used. If desired, at least one of the plurality of second insulating layers 211, 212, and 213, for example, the 2-1 insulating layer 211 may include other types of insulating materials other than the organic insulating material such as glass and ceramic. However, even in this case, the other 2-2 and 2-3 insulating layers 212 and 213 may include an organic insulating material. The 2-1 insulating layer 211 may be a core layer, and each of the 2-2 and 2-3 insulating layers 212 and 213 may be a build-up layer. The 2-1 insulating layer 211 may have a thickness greater than those of the 2-2 and 2-3 insulating layers 212 and 213.

Each of the plurality of second wiring layers 221, 222, 223, and 224 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an example embodiment thereof is not limited thereto. Each of the plurality of second wiring layers 221, 222, 223, and 224 may perform various functions depending on a design. For example, a signal pattern, a power pattern, and a ground pattern may be included. Each of the patterns may have various forms such as a line, a plain, and a pad. The plurality of second wiring layers 221, 222, 223, and 224 may include a seed layer and a plating layer formed on the seed layer. The seed layer may be an electroless plating layer (or chemical copper) and/or a sputtering layer, and the plating layer may be an electrolytic plating layer (or electrical copper), but an example embodiment thereof is not limited thereto. The 2-1 and 2-2 wiring layers 221 and 222 may be disposed on a lower surface and an upper surface of the 2-1 insulating layer 211, respectively, and the 2-3 and 2-4 wiring layers may be disposed on a lower surface of the 2-2 insulating layer 212 and an upper surface of the 2-3 insulating layer 213, respectively, but an example embodiment thereof is not limited thereto.

The second antenna pattern P2 may include a patch pattern. The patch pattern may receive an RF signal through a feeding pattern and a feeding via in the first and second substrates 100 and 200 and may transmit the signal in the thickness direction (Z-direction). The RF signal received in the thickness direction may be transmitted to an electronic component mounted on the substrate, such as a radio frequency integrated circuit (RFIC), through the feeding pattern and the feeding via in the first and second substrates 100 and 200. The patch pattern may have an intrinsic resonance frequency, for example, 28 GHz, 39 GHz, or the like, depending on intrinsic factors such as a shape of the pattern, a size and a height of the pattern, a dielectric constant of the insulating layer, and a dielectric constant of the air gap. For example, the patch pattern may be electrically connected to a radio frequency integrated circuit (RFIC) and may transmit and receive, for example, a horizontal pole (H-pole) RF signal and a vertical pole (V-pole) RF signal polarized to each other.

The second metal layer M2 may include various types of conductor patterns. For example, the second metal layer M2 may include a conductor pattern such as a line, a pad, and a plane. The second metal layer M2 may be disposed in a position substantially corresponding to the first metal layer M1, and the conductor pattern of the second metal layer M2 may have a shape substantially corresponding to the conductor pattern of the first metal layer M1. The 2-3 wiring layer 223 including the second metal layer M2 may be planarized as in a process described later, and may thus have a thickness smaller than those of the other 2-1, 2-2, and 2-4 wiring layers 221, 222, and 224. For example, the second metal layer M2 may have a thickness smaller than that of the second antenna pattern P2.

Each of the plurality of second via layers 231, 232, and 233 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an example embodiment thereof is not limited thereto. Each of the plurality of second via layers 231, 232, and 233 may include a filled via filling a via hole, but may also include a conformal via disposed along a wall surface of the via hole. The plurality of second via layers 231, 232, and 233 may perform various functions depending on a design. For example, a ground via, a power via, and a signal vias may be included. The plurality of second via layers 231, 232, and 233 may include an electroless plating layer (or chemical copper) and an electrolytic plating layer (or electric copper), respectively. A sputtering layer may be included instead of an electroless plating layer (or chemical copper), or, if desired, both may be included. The 2-1 via layer 231 may have an hourglass or a pillar shape in a cross-section. The 2-2 and 2-3 via layers 232 and 233 may have a tapered shape in opposite directions in a cross-section.

Among the plurality of first via layers 131, 132, and 133, the 1-2 via layer 132 disposed on an uppermost side may include a first connection via connected to the first metal layer M1, and among the plurality of second via layers 231, 232, and 233, the 2-2 via layer 232 disposed on a lowermost side thereof may include a second connection via connected to the second metal layer M2. The first and second connection vias may be tapered in opposite directions. For example, a width of an upper end of a first connection via may be wider than a width of a lower end in a cross-section. A width of a lower end of the second connection via may be wider than a width of an upper end in a cross-section.

The bonding layer 300 may include an insulating material used for hybrid metal bonding. For example, the bonding layer 300 may include an inorganic insulating material. The inorganic insulating material may include, for example, an inorganic oxide film or an inorganic nitride film, and more specifically, the material may include at least one of SiO₂, SiN and SiCN, but an example embodiment thereof is not limited thereto. The bonding layer 300 may cover at least a portion of each of the first and second metal layers M1 and M2. For example, the bonding layer 300 may cover at least a portion of a side surface of each of the first and second metal layers M1 and M2. However, the bonding layer 300 may be spaced apart from a lower surface of the first metal layer M1 and an upper surface of the second metal layer M2. In a region in which a cavity C is not formed, for example, in a region not overlapping the cavity C on a plane, a thickness of the bonding layer 300 may be substantially the same as a thickness of the metal layer M.

The cavity C may be disposed between the first and second antenna patterns P1 and P2 and may provide an air gap structure. For example, at least a portion of the cavity C may be filled with air. The cavity C may penetrate a portion of the second substrate 200. For example, the cavity C may penetrate the 2-2 insulating layer 212. However, an example embodiment thereof is not limited thereto, and if desired, at least a portion of each of the 2-1 insulating layer 211 and/or the 2-3 insulating layer 213 may be further penetrated. For example, a depth of the air gap may be freely adjusted. Also, the cavity C may penetrate a portion of the bonding layer 300. Accordingly, a bottom surface of the cavity C may include a bonding layer 300, and a wall surface of the cavity C may expose a portion of a side surface of the bonding layer 300, but an example embodiment thereof is not limited thereto. From this perspective, a thickness of the bonding layer 300 between the first substrate 100 and the cavity C may have a thickness smaller than the thickness between the first and second substrates 100 and 200, but an example embodiment thereof is not limited thereto.

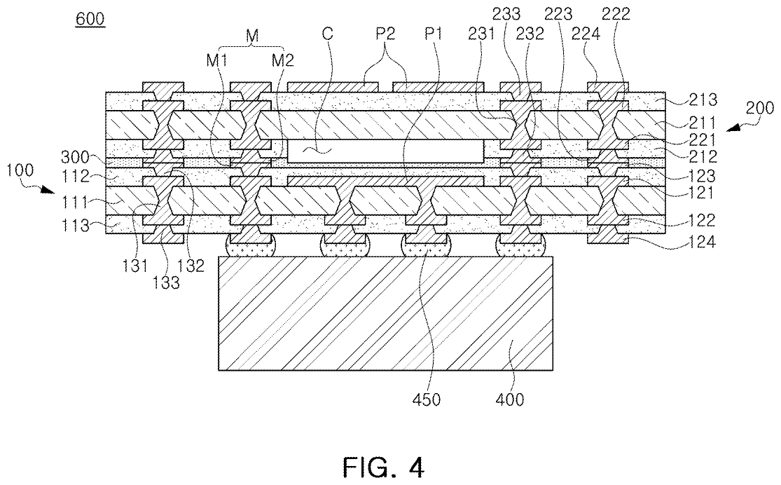

FIG. 4 is a cross-sectional diagram illustrating another example of a printed circuit board.

Referring to the drawings, the printed circuit board 600 according to another example may further include a semiconductor chip 400 mounted on a lower side of the first substrate 100 in a printed circuit board 500 according to the above-described example. For example, the printed circuit board 500 according to an example may have an antenna substrate structure, and the printed circuit board 600 according to another example may have an antenna module structure including the same. The semiconductor chip 400 may be connected to the wiring layer 124 of the first substrate 100 through the connection member 450.

There may be one or more semiconductor chips 400, and may include a radio frequency integrated circuit (RFIC), a power management IC (PMIC), or the like. If desired, along with the semiconductor chip 400, a chip-type passive component, for example, a chip-type capacitor or a chip-type inductor, may be further mounted on a lower side of the first substrate 100.

The connection member 450 may be formed of a low melting point metal, for example, solder such as tin (Sn)-aluminum (Al)-copper (Cu), but this is merely an example and the material is specifically limited thereto. The connection member 450 may be a ball, a pin, or the like. The connection member 450 may include multiple layers or a single layer. When the connection member 450 includes multiple layers, a copper pillar and solder may be included, and when the connection member 450 includes a single layer, tin-silver solder may be included, but an example embodiment thereof is not limited thereto. A plurality of the connection members 450 may be included, and the number of the connection members 450 is not limited to any particular example.

Other descriptions may be substantially the same as the descriptions of the printed circuit board 500 according to the above-described example. Accordingly, overlapping descriptions may not be provided.

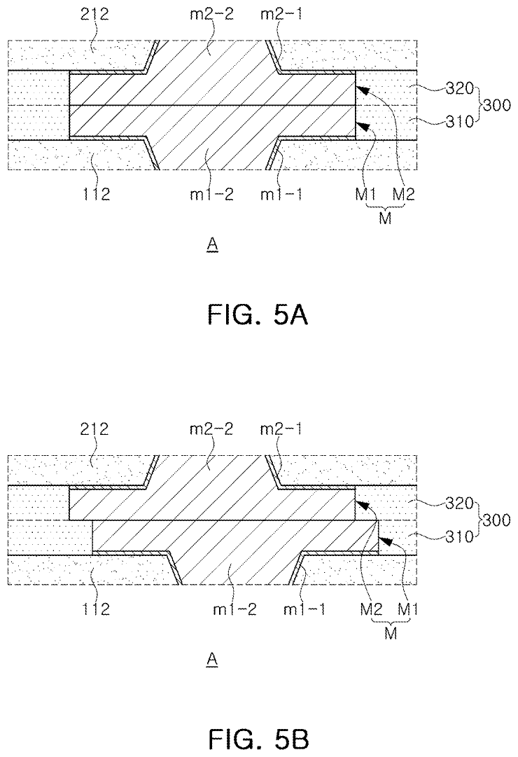

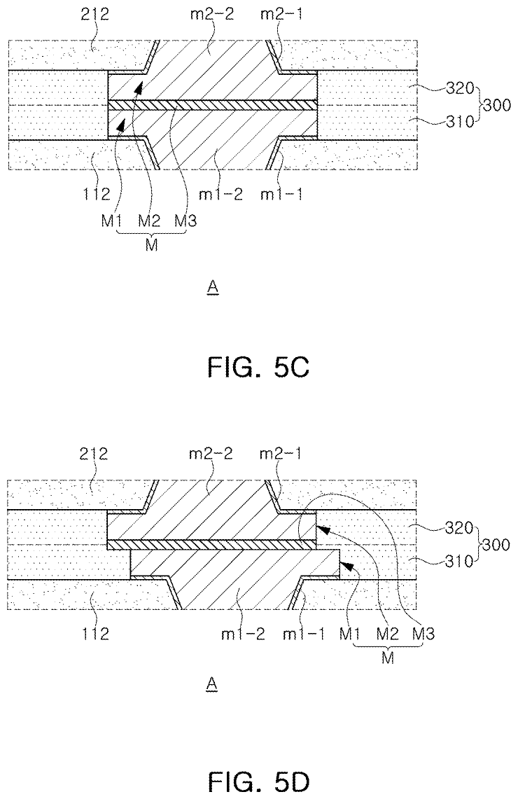

FIGS. 5A to 5D are enlarged cross-sectional diagram illustrating various examples of hybrid metal bonding.

Referring to FIG. 5A, an upper surface of the first metal layer M1 and a lower surface of the second metal layer M2 may be directly bonded to each other. For example, the metal layer M may be formed by directly bonding the first and second metal layers M1 and M2 to each other. A boundary between the first and second metal layers M1 and M2 may be distinct. The first metal layer M1 may include a 1-1 metal layer m1-1, which is a seed layer, and a 1-2 metal layer m1-2, which is a plating layer. The second metal layer M2 may also include a 2-1 metal layer m2-1, which is a seed layer, and a 2-2 metal layer m2-2, which is a plating layer. Each of the layers may include the above-described metal, preferably copper (Cu), but an example embodiment thereof is not limited thereto. The bonding layer 300 may include first and second insulating films 310 and 320. The first and second insulating films 310 and 320 may be inorganic insulating films. The films may include the inorganic insulating material described above, preferably SiO₂, but an example embodiment thereof is not limited thereto. The first insulating film 310 may be disposed on an upper side of the first substrate 100 and may cover at least a portion of a side surface of the first metal layer M1. The second insulating film 320 may be disposed on a lower side of the second substrate 200 and may cover at least a portion of a side surface of the second metal layer M2. A boundary between the first and second insulating films 310 and 320 may be indistinct, and for example, the films may be integrated with each other. The first and second metal layers M1 and M2 and the first and second insulating films 310 and 320 may be bonded to each other through hybrid metal bonding. An upper surface of the first metal layer M1 and an upper surface of the first insulating film 310 may be coplanar with each other, a lower surface of the second metal layer M2 and a lower surface of the second insulating film 320 may be coplanar with each other, but an example embodiment it is not limited thereto. The bonding structure may be applied to the printed circuit board 500 according to the above-described example and the printed circuit board 600 according to another example.

Referring to FIG. 5B, the first metal layer M1 and the second metal layer M2 may be bonded to each other such that side surfaces thereof may be shifted from each other. For example, at least a portion of a side surface of metal layer M may have a step difference. Here, the step difference may include the step difference between vertical side surfaces, and also the step difference between curved side surfaces including outwardly curved and inwardly curved shapes. For example, even when a side surface of the metal layer M may be S-shaped, when an upper end and a lower end of the metal layer M may be sufficiently shifted from each other, a step difference may be obtained. For example, a step difference may be the step difference caused by misalignment between the first and second metal layers M1 and M2 when bonding, and may be distinct from simply unevenness formed on a side surface, such as surface roughness or surface roughness. In this case, the bonding layer 300 may further cover at least a portion of each of an upper surface of the first metal layer M1 and a lower surface of the second metal layer M2. Accordingly, improved adhesion may be obtained. Accordingly, reliability may be further improved. Other descriptions are the same as the descriptions of the bonding structure in FIG. 5A. The bonding structure may also be applied to the printed circuit board 500 according to the above-described example and the printed circuit board 600 according to another example.

Referring to FIG. 5C, an upper surface of the first metal layer M1 and a lower surface of the second metal layer M2 may be bonded to each other through the third metal layer M3 including a different metal from the first and second metal layers M1 and M2. For example, a heterogeneous metal layer M3 may be disposed in the metal layer M. For example, the first and second metal layers M1 and M2 may include copper (Cu), and the third metal layer M3 may include silver (Ag) or gold (Au), but an example embodiment thereof is not limited thereto. When the third metal layer M3 is used, adhesion between the first and second metal layers M1 and M2 may be improved. Other descriptions may be the same as the descriptions of the bonding structure in FIG. 5A. The bonding structure may also be applied to the printed circuit board 500 according to the above-described example and the printed circuit board 600 according to another example.

Referring to FIG. 5D, an upper surface of the first metal layer M1 and a lower surface of the second metal layer M2 may be bonded to each other through the third metal layer M3 including a different metal from the first and second metal layers M1 and M2. For example, a heterogeneous metal layer M3 may be disposed in the metal layer M. For example, the first and second metal layers M1 and M2 may include copper (Cu), and the third metal layer M3 may include silver (Ag) or gold (Au). In this case, adhesion between the first and second metal layers M1 and M2 may be improved. Also, the first metal layer M1 and the second metal layer M2 may be bonded to each other such that side surfaces may be shifted from each other. For example, at least a portion of a side surface of the metal layer M may have a step difference. Here, the step difference may include the step difference between vertical side surfaces, and also the step difference between curved side surfaces including outwardly curved or inwardly curved shapes. For example, even when the side surface of the metal layer M is S-shaped, when an upper end and a lower end of the metal layer M are sufficiently shifted from each other, a step difference may be obtained. For example, the step difference may refer to the step difference due to misalignment between the first and second metal layers M1 and M2 during bonding, and a step difference may be distinguished from an unevenness formed on a side surface, such as surface roughness or surface roughness. In this case, the bonding layer 300 may further cover at least a portion of an upper surface of the first metal layer M1 and a lower surface of the second metal layer M2, and accordingly, adhesion and reliability may be improved. Also, at least a portion of the third metal layer M3 may be disposed to deviate from at least one of an upper surface of the first metal layer M1 and a lower surface of the second metal layer M2. For example, a portion of the third metal layer M3 may be disposed to extend beyond the upper surface of the first metal layer M1, and in this case, a portion of the lower surface of the third metal layer M3 may be in contact with the bonding layer 300, and adhesion may be improved. Alternatively, for example, a portion of the third metal layer M3 may be disposed to extend beyond the lower surface of the second metal layer M2, and in this case, a portion of the upper surface of the third metal layer M3 may be in contact with the bonding layer 300 and adhesion may be improved. Other descriptions may be the same as the descriptions of the bonding structure in FIG. 5A. The bonding structure may also be applied to the printed circuit board 500 according to the above-described example and the printed circuit board 600 according to another example.

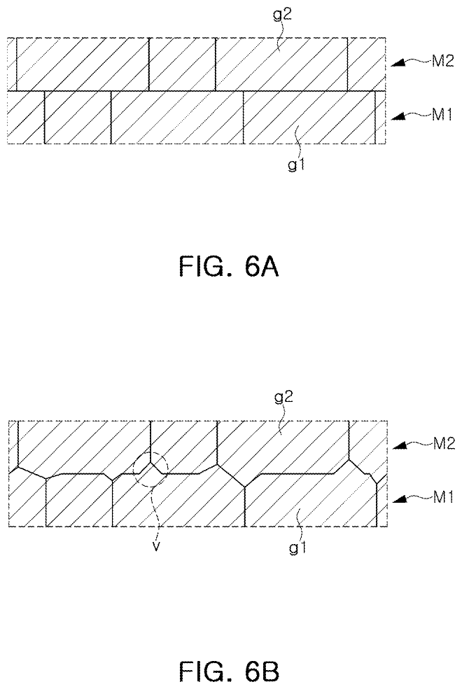

FIGS. 6A and 6B are enlarged cross-sectional diagram illustrating various examples of a boundary surface in intermetallic bonding.

Referring to FIG. 6A, in the case in which the first metal layer M1 and the second metal layer M2 are directly bonded to each other by hybrid metal bonding, the first metal layer M1 and the second metal layer M2 may include a plurality of first and second grains g1 and g2, respectively. In this case, in an intermetallic bonding boundary surface between the first and second metal layers M1 and M2, the plurality of first grains g1 and the plurality of second grains g2 may include, for example, a plurality of triple junctions at approximately 90 degrees. The intermetallic bonding boundary surface may be applied to the printed circuit board 500 according to the above-described example and the printed circuit board 600 according to another example.

Referring to FIG. 6B, a boundary surface of intermetallic bonding may have a diffusion wedge due to a decrease in the surface energy of a grain boundary. For example, the boundary surface between the upper surface of the first metal layer M1 and the lower surface of the second metal layer M2 may have a protrusion v protruding inwardly of at least one of the first metal layer M1 and the second metal layer M2, and the protrusion v may include a diffusion wedge caused by diffusion of metal particles. For example, in the intermetallic bonding boundary surfaces between the first and second metal layers M1 and M2, the plurality of first grain g1 and the plurality of second grain g2 may include a plurality of triple junctions, for example, approximately 120 degrees. The intermetallic bonding boundary surface may also be applied to the printed circuit board 500 according to the above-described example and the printed circuit board 600 according to another example.

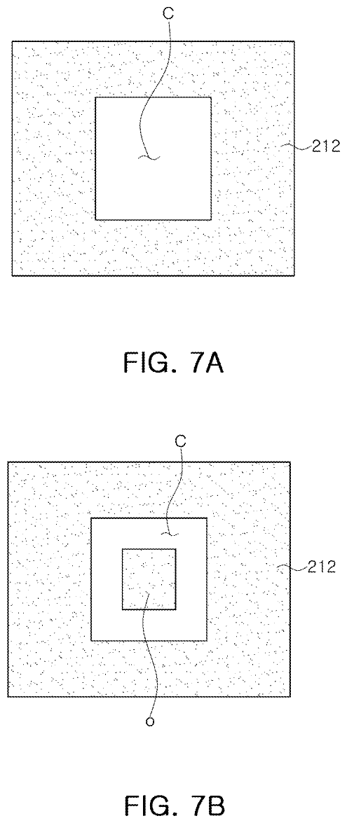

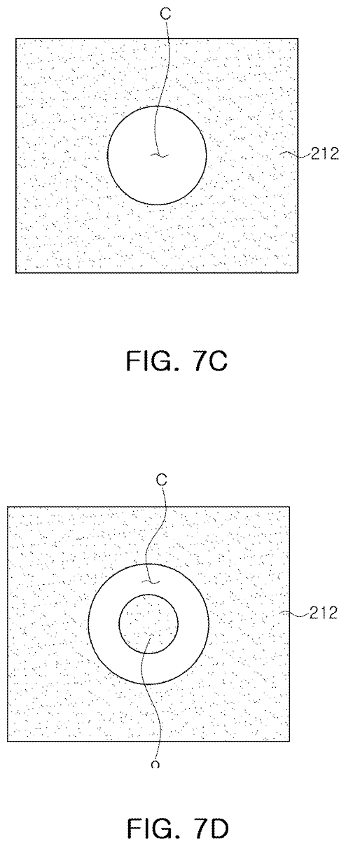

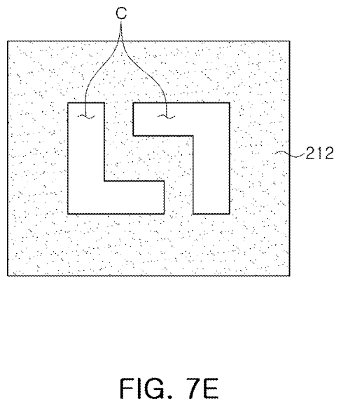

FIGS. 7A to 7E are plan diagrams illustrating various examples of a cavity.

Referring to FIGS. 7A to 7E, on a plane, a cavity C may have various shapes such as a rectangular shape, a circular shape, a “ [symbol] ” shape, a “ [symbol] ” shape, a shape in which island o is disposed in a rectangular or circular space. In this case, the island o may include the 2-2 insulating layer 212, and may be spaced apart from a wall surface of the cavity C. Here, the wall surface may be a surface providing an edge of the cavity C on a plane. Also, a plurality of the cavities C may be formed. As such, the cavity C used as an air gap may be formed in various shapes without any particular limitations, and accordingly, antenna performance may be increased. For ease of description, components other than the 2-2 insulating layer 212 and the cavity C may be increased. The cavities C having the shape as above may be applied to the printed circuit board 500 according to the above-described example and the printed circuit board 600 according to another example.

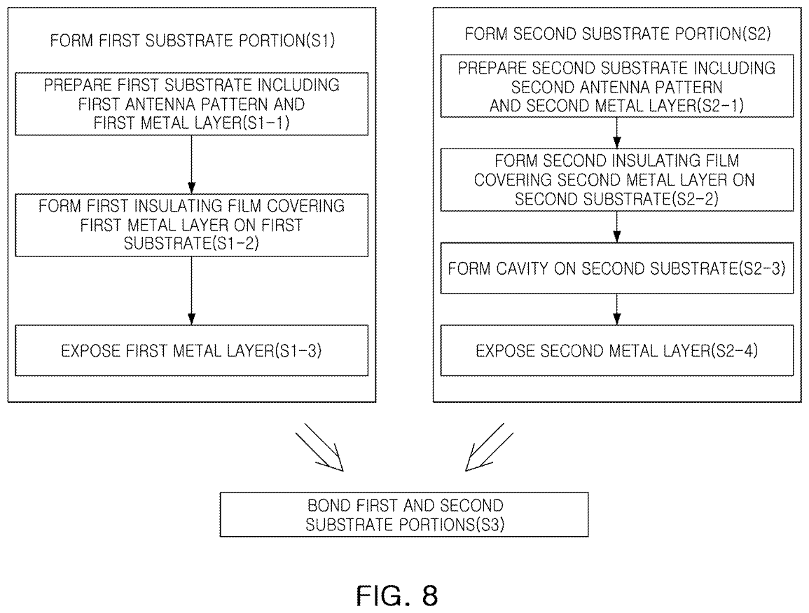

FIG. 8 is a diagram illustrating an example of a method of manufacturing a printed circuit board.

Referring to the drawings, the method of

manufacturing a printed circuit board according to an example may include forming a first substrate portion (S1), forming a second substrate portion (S2), and bonding the first and second substrate portions (S3). The forming the first substrate portion (S1) may include preparing the first substrate including the first antenna pattern and the first metal layer (S1-1), forming the first insulating film covering the first metal layer on the first substrate (S1-2), and exposing the first metal layer (S1-3). The forming the second substrate portion (S2) may include preparing a second substrate including a second antenna pattern and a second metal layer (S2-1), forming a second insulating film covering the second metal layer on the second substrate (S2-2), forming a cavity in the second substrate (S2-3), and exposing the second metal layer (S2-4).

Hereinafter, the method of manufacturing a printed circuit board according to an example will be described in greater detail with reference to the drawings.

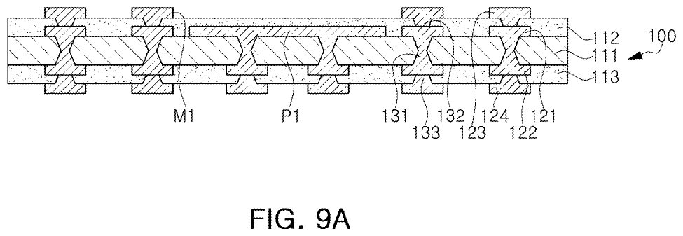

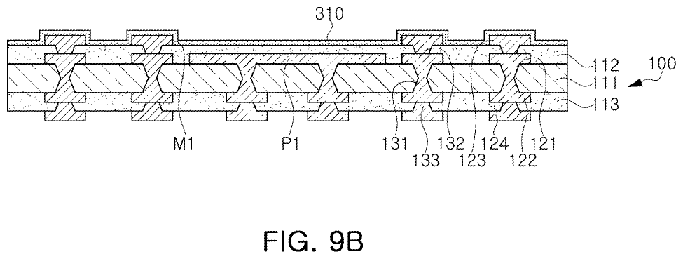

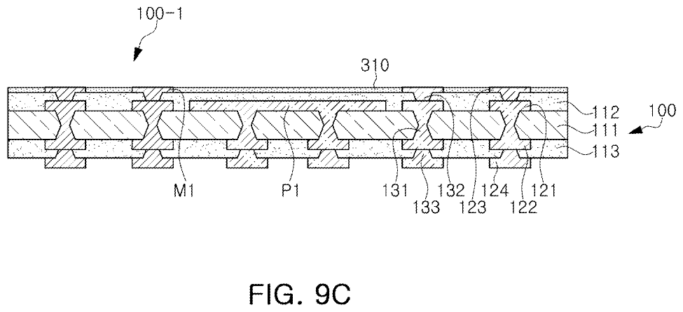

FIGS. 9A to 9C are cross-sectional diagrams illustrating an example of processes of manufacturing a first substrate portion.

Referring to FIG. 9A, a first substrate 100 including a first antenna pattern P1 and having a first metal layer M1 formed on one side may be prepared. The first substrate 100 may be configured as a multilayer organic substrate as described above. The first substrate 100 may be formed using a substrate process, such as a double-sided build-up process or a coreless process.

Referring to FIG. 9B, a first insulating film 310 covering at least a portion of first metal layer M1 may be formed on one side of the first substrate 100. The first insulating film 310 may be an inorganic insulating film as described above. The first insulating film 310 may be formed through a coating process such as deposition. The first insulating film 310 may conformally cover the first substrate 100 and the first metal layer M1, but an example embodiment thereof is not limited thereto.

Referring to FIG. 9C, the surface of the first metal layer M1 may be exposed by planarizing the first metal layer M1 and the first insulating film 310. As the planarization process, grinding process may be used. Through the planarized process, thicknesses of the first metal layer M1 and the first insulating film 310 may become substantially the same. Also, the thickness of the first metal layer M1 may have a thickness smaller than that of each of the other 1-1, 1-2, and 1-4 wiring layers 121, 122, and 124.

Through a series of processes, the first substrate portion 100-1 may be prepared. Other descriptions may be substantially the same as the description of the printed circuit board 500 according to the above-described example, and overlapping descriptions will not be provided.

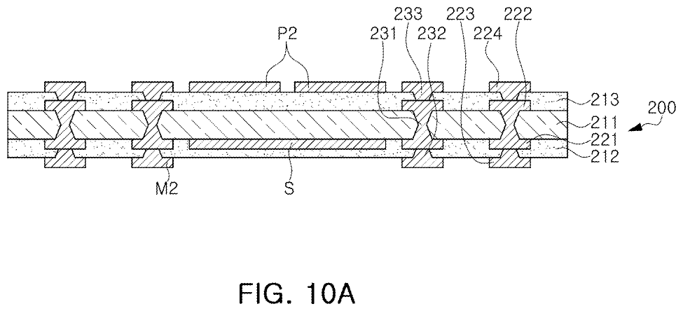

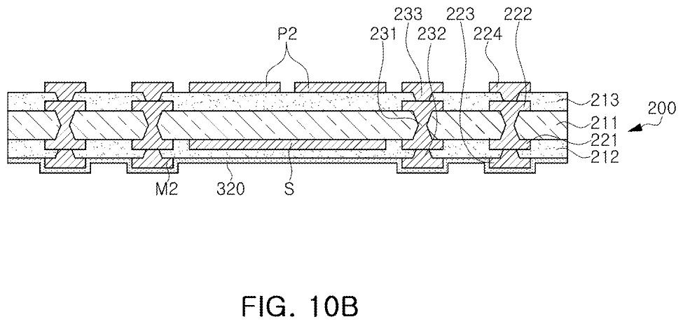

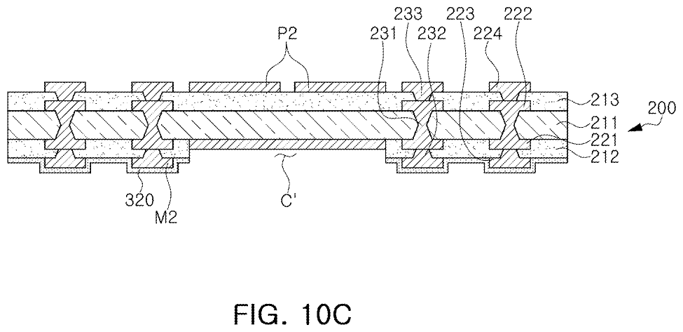

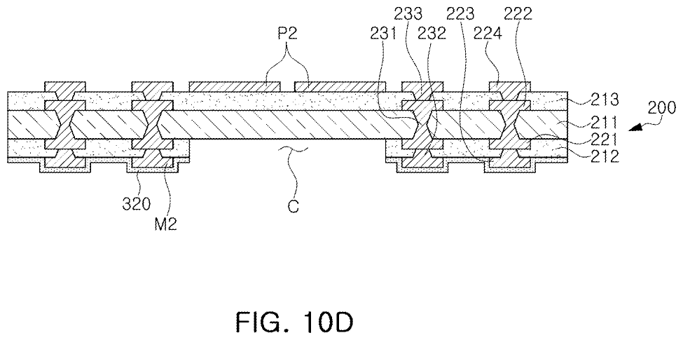

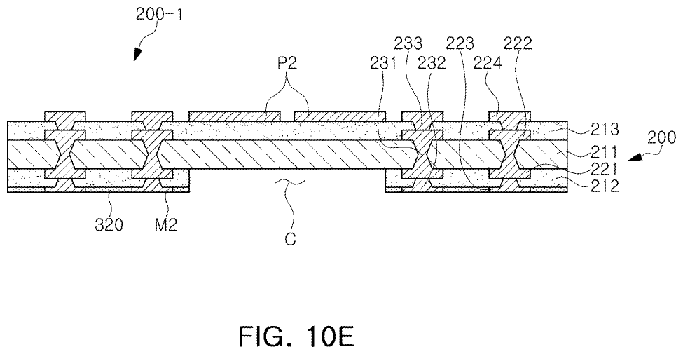

FIGS. 10A to 10E are cross-sectional diagrams illustrating an example of processes of manufacturing a second substrate portion.

Referring to FIG. 10A, a second substrate 200 including a second antenna pattern P2 and including a second metal layer M2 formed on one side thereof may be prepared. The second substrate 200 may be a multilayer organic substrate as described above. The second substrate 200 may be formed using a substrate process, such as a double-sided build-up process or a coreless process.

Referring to FIG. 10B, a second insulating film 320 covering at least a portion of the second metal layer M2 may be formed on one side of the second substrate 200. The second insulating film 320 may be an inorganic insulating film as described above. The second insulating film 320 may be formed through a coating process such as deposition. The second insulating film 320 may conformally cover the second substrate 200 and the second metal layer M2, but an example embodiment thereof is not limited thereto.

Referring to FIG. 10C, a cavity C′ may be formed on the second substrate 200. For example, the cavity C′ penetrating the second insulating film 320 and also penetrating a portion of the second substrate 200 may be formed in the second substrate 200. The cavity C′ may be formed by various methods, such as a blast process and a laser process. If desired, the cavity C′ may be formed on the first substrate 100.

Referring to FIG. 10D, a stopper layer S may be removed. The stopper layer S may be removed by chemical etching. Alternatively, the stopper layer S may be removed by grinding. For example, the stopper layer S may be removed during a planarized process, such as a grinding process, which will be described later. If desired, the stopper layer S may not be provided, and in this case, the process of removing the stopper layer S may not be performed. When stopper layer S is removed, the cavity C having a greater depth may be formed.

Referring to FIG. 10E, by planarizing the second metal layer M2 and the second insulating film 320, the surface of the second metal layer M2 may be exposed. As the planarized process, a grinding process may be used. Through the planarization process, thicknesses of the second metal layer M2 and the second insulating film 320 may become substantially the same. Also, a thickness of the second metal layer M2 may have a thickness smaller than that of each of the other 2-1, 2-2, and 2-4 wiring layers 221, 222, and 224.

Through a series of processes, the second substrate portion 200-1 may be prepared. Other descriptions may be substantially the same as the description of the printed circuit board 500 according to the above-described example, and overlapping descriptions will not be provided.

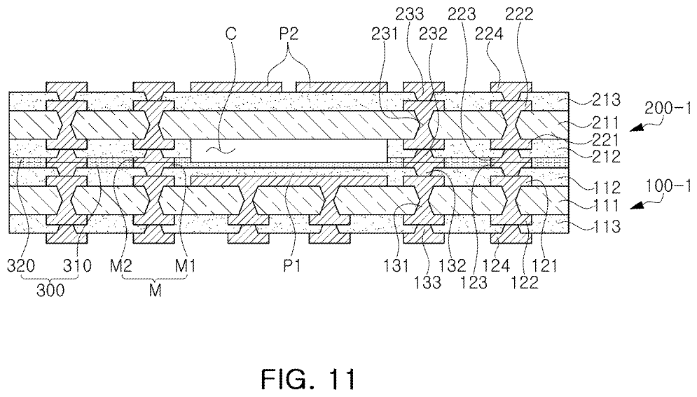

FIG. 11 is a cross-sectional diagram illustrating an example of bonding of first and second substrate portions.

Referring to the drawing, the first and second substrate portions 100-1 and 200-1 may be bonded to each other by bonding the first and second insulating film 310, 320 to each other and bonding the first and second metal layers M1 and M2 to each other. Hybrid metal bonding described later may be used for bonding the first and second insulating films 310 and 320 and the first and second metal layers M1 and M2 to each other.

Through a series of processes, the printed circuit board 500 according to the above-described example may be manufactured. Other descriptions may be substantially the same as the description of the printed circuit board 500 according to the above-described example, and overlapping descriptions will not be provided.

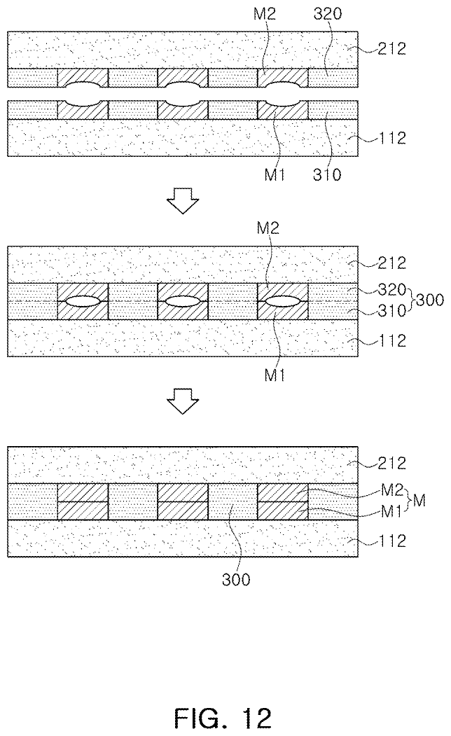

FIG. 12 is a cross-sectional diagram illustrating processes of hybrid metal bonding according to an example embodiment.

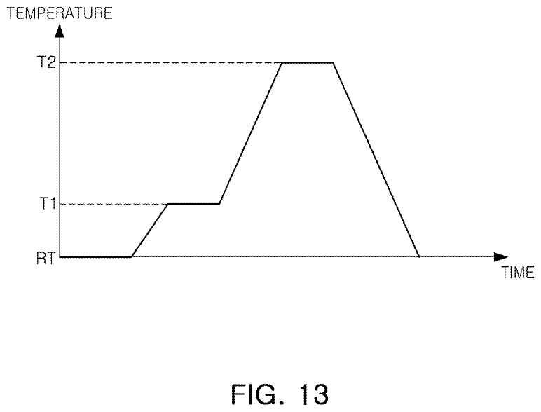

FIG. 13 is a graph indicating a temperature cycle of hybrid metal bonding according to an example embodiment.

Referring to the drawing, first and second insulating films 310 and 320 may be in contact with each other, and also first and second metal layers M1 and M2 may be in contact with each other. Before contact, surfaces of the first and second insulating films 310 and 320 and the first and second metal layers M1 and M2 may be treated by wet cleaning or plasma activation. In this case, a recess may be formed in a surface of each of the first and second metal layers M1 and M2. The first and second insulating films 310 and 320 and the first and second metal layers M1 and M2 may be in contact with each other at room temperature RT. Thereafter, the first and second insulating films 310 and 320 may be bonded to each other at the first temperature. For example, at the first temperature T1, the first and second insulating films 310 and 320 may be directly bonded to and integrated with each other through the bonding layer 300. The first temperature T1 may be lower than the second temperature T2. Thereafter, the first and second metal layers M1 and M2 may be bonded to each other at the second temperature T2. For example, at the second temperature T2, the first and second metal layers M1 and M2 may be directly bonded to each other and the metal layer M may be formed. For example, during the annealing process at the second temperature T2, the first and second metal layers M1 and M2 may be bonded to each other by coupling by increasing a size of grain of the metal. The second temperature T2 may be a higher temperature than the first temperature T1. When the first and second insulating films 310 and 320 and the first and second metal layers M1 and M2 are bonded to each other, the bottom surface of the cavity C may be blocked with the bonding layer 300, for example, the second insulating film 320.

Through a series of processes, the above-described first and second substrate portions 100-1 and 100-2 may be bonded to each other. Other descriptions may be substantially the same as the description of the printed circuit board 500 according to the above-described example, and overlapping descriptions will not be provided.

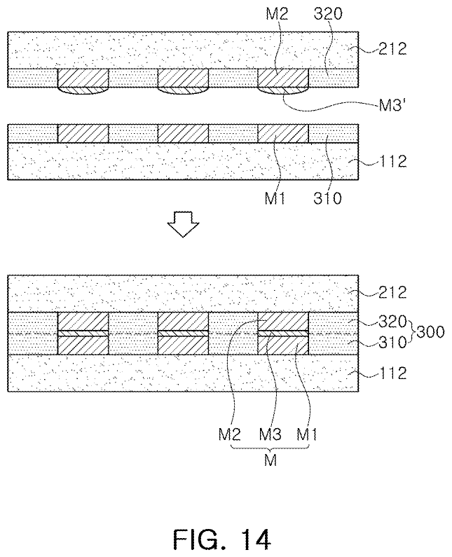

FIG. 14 is cross-sectional diagrams illustrating another example of hybrid metal bonding according to an example embodiment.

Referring to the drawings, the bonding the first and second substrate portions 100-1 and 100-2 to each other may further include applying a metal paste M3′ including a metal different from the first and second metal layers M1 and M2 between the first and second metal layers M1 and M2. For example, before allowing the first and second insulating films 310 and 320 and the first and second metal layers M1 and M2 to be in contact with each other, a metal paste M3′ may be applied on an upper surface of the first metal layer M1 and/or a lower surface of the second metal layer M2. Thereafter, through the above-described thermal compression process, the first and second insulating films 310 and 320 may be directly bonded to each other, and the first and second metal layers M1 and M2 may also be bonded to each other through the third metal layer M3. Accordingly, the bonding layer 300 and metal layer M may be formed. When the first and second insulating films 310 and 320 and the first to third metal layers M1, M2, and M3 are bonded to each other, a bottom surface of the cavity C may be blocked with the bonding layer 300, for example, the second insulating film 320.

Through a series of processes, the above-described first and second substrate portions 100-1 and 100-2 may be bonded to each other. Other descriptions may be substantially the same as the description of the printed circuit board 500 according to the above-described example, and overlapping descriptions will not be provided.

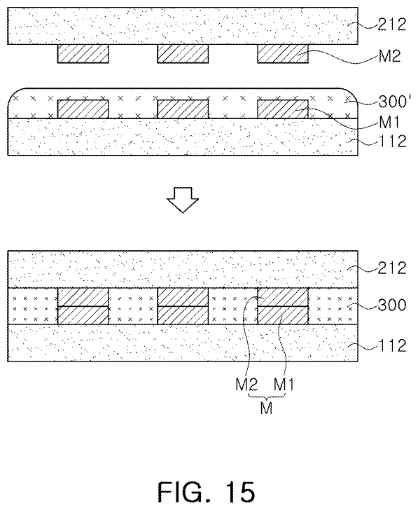

FIG. 15 is cross-sectional diagrams illustrating another example of hybrid metal bonding according to an example embodiment.

Referring to the drawing, the first and second metal layers M1 and M2 may be formed of nano-twinned copper instead of general copper, and the bonding layer 300 may be formed of non-conductive paste. For example, the non-conductive paste 300′ may be applied on the first metal layer M1 formed as a nano-twinned copper film, the second metal layer M2 formed as a nano-twinned copper film may be pressed, thereafter, bonding may be performed at high temperature, and the first and second metal layers M1 and M2 may be directly bonded to each other. Alternatively, the non-conductive paste 300′ may be applied on the second metal layer M2 formed as a nano-twinned copper film, the first metal layer M1 formed as a nano-twinned copper film may be pressed, thereafter, bonding may be performed at a high temperature, and the first and second metal layers M1 and M2 may also be directly bonded to each other. Accordingly, the metal layer M2 and the bonding layer 300 burying the same may be formed. If desired, the non-conductive paste 300′ may be applied while the above-mentioned first insulating film 310 and/or the second insulating film 320 are formed, and in this case, the bonding layer 300 may include a first insulating film 310 and/or a second insulating film 320. When a cured product of non-conductive paste 300′ and the first and second metal layers M1 and M2 are bonded to each other, a bottom surface of the cavity C may be blocked by the bonding layer 300, for example, the cured product of the non-conductive paste 300′ may be blocked. If desired, a bottom surface of the cavity C may be blocked in advance using an appropriate substance.

According to the aforementioned example embodiments, a printed circuit board including an antenna pattern and having an air gap structure may be provided.

Also, a printed circuit board which may increase antenna performance may be provided.

In the present disclosure, the term “covering” may include the configuration in which the component is entirely covered and at least a portion of the component is covered, or the component is directly or indirectly covered. Also, the term “fill” may include the configuration in which the component is completely filled, and also at least a portion of the component is filled, and the component is almost filled. For example, a void may be present. Also, the term “surrounding” may include the configuration in which the component is completely surrounded, and is also almost surrounded. Also, the term “exposing” may include the configuration in which the component is completely exposed or a portion thereof is exposed, and the exposing may refer to exposing from the buried component. For example, the configuration in which the opening may expose a pad may include exposing a pad from the resist layer, and a surface treatment layer may be further disposed on the exposed pad.

In the example embodiment, the configuration in which the component is disposed in a through-portion or a through-hole may include the configuration in which the component is completely disposed in the through-portion or through-hole, and also the configuration in which the component partially protrudes to an upper side or a lower side on a cross-section. For example, in the case in which the component is disposed in a through-portion or through-hole on a plane, the configuration may be understood in a broader sense.

In the present disclosure, the term “cross-section” refers to the cross-sectional shape when the object is cut vertically, or the cross-sectional shape when the object is cut vertically, or the cross-sectional shape when the object is viewed from the side. Also, the configuration in which the components are on a plane may indicate a planar shape when the object is cut horizontally, or a planar shape when the object is viewed from above or below.

In the present disclosure, the terms “lower side,” “lower portion,” and “lower surface” may be used to refer to a downward direction based on the cross-section of the drawing, and “upper side,” “upper portion,” “upper surface” may be used to refer to the opposite direction. However, this direction is defined for ease of description, and the scope of the patent claims is not particularly limited by the description of the direction, and the terms “upper and lower sides” may be relative terms.

In the example embodiments, the term “connected” may not only refer to “directly connected” but also include “indirectly connected” by may refer to of an adhesive layer, or the like. Also, the term “electrically connected” may include both of the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

A thickness, width, length, depth, line width, distance, pitch, and the like, may be measured using a scanning microscope or optical microscope based on a cross section of a printed circuit board which may be polished or cut. The cross-section may be a vertical cross-section or a horizontal cross-section, and each value may be measured based on the required cross-section. For example, a width of an upper end and/or lower end of a via may be measured on a cross-section cut along a central axis of the via. In this case, when the value is not constant, the value may be determined as an average value of the values measured at five random points. A minimum value may be determined as the lowest value measured on the corresponding layer or region.

In the example embodiments, the term “example embodiment” may not refer to one same example embodiment, and may be provided to describe and emphasize different unique features of each example embodiment. The above suggested example embodiments may be implemented do not exclude the possibilities of combination with features of other example embodiments. For example, even though the features described in an example embodiment are not described in the other example embodiment, the description may be understood as relevant to the other example embodiment unless otherwise indicated.

An expression used in the singular encompasses the expression of the plural, unless it has a clearly different meaning in the context.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
a first substrate including a first antenna pattern;
a second substrate disposed on a first substrate and including a second antenna pattern;
a metal layer disposed between the first and second substrates; and
a bonding layer disposed between the first and second substrates,
wherein at least one of the first and second substrates has a cavity having at least a portion disposed between the first and second antenna patterns,
wherein each of the first and second substrates includes an organic material, and
wherein the bonding layer: includes an inorganic material.

2. The printed circuit board of claim 1,
wherein the metal layer includes a first metal layer disposed on an uppermost side of the first substrate and a second metal layer disposed on a lowermost side of the second substrate.

3. The printed circuit board of claim 2,
wherein the first and second metal layers are bonded to each other such that side surfaces thereof are shifted from each other.

4. The printed circuit board of claim 2, wherein an upper surface of the first metal layer and a lower surface of the second metal layer are directly bonded to each other.

5. The printed circuit board of claim 4, wherein a boundary surface between the upper surface of the first metal layer and the lower surface of the second metal layer has a protrusion protruding inwardly of at least one of the first and second metal layers.

6. The printed circuit board of claim 5, wherein the protrusion includes a diffusion wedge of metal particles.

7. The printed circuit board of claim 2, wherein the metal layer includes a third metal layer disposed between the first and second metal layers and including a metal different from that of the first and second metal layers.

8. The printed circuit board of claim 7, wherein at least a portion of the third metal layer is disposed beyond at least one of an upper surface of the first metal layer and a lower surface of the second metal layer.

9. The printed circuit board of claim 7,
wherein the first and second metal layers include copper (Cu), and
wherein the third metal layer includes silver (Ag) or gold (Au).

10. The printed circuit board of claim 2,
wherein the first metal layer has a thickness smaller than that of the first antenna pattern, and
wherein the second metal layer has a thickness smaller than that of the second antenna pattern.

11. The printed circuit board of claim 1, wherein the bonding layer includes an inorganic insulating film.

12. The printed circuit board of claim 11, wherein the inorganic insulating film includes SiO₂, SiN or SiCN.

13. The printed circuit board of claim 1,
wherein the first antenna pattern includes a coupling pattern, and
wherein the second antenna pattern includes a patch pattern.

14. The printed circuit board of claim 1, wherein at least a portion of the cavity is filled with air.

15. The printed circuit board of claim 1, wherein the cavity penetrates a portion of the second substrate.

16. The printed circuit board of claim 15, wherein a bottom surface of the cavity includes the bonding layer.

17. The printed circuit board of claim 16,
wherein the cavity further penetrates a portion of the bonding layer, and
wherein a wall surface of the cavity exposes a portion of an internal side surface of the bonding layer.

18. The printed circuit board of claim 16, wherein a thickness of the bonding layer between the first substrate and the cavity is smaller than a thickness between the first and second substrates.

19. The printed circuit board of claim 1, wherein an island spaced apart from a wall surface of the cavity is disposed in the cavity.

20. The printed circuit board of claim 1,
wherein the first substrate includes a plurality of first insulating layers, a plurality of first wiring layers disposed on or in the plurality of first insulating layers, respectively, and a plurality of first via layers penetrating at least one of the plurality of first insulating layers, respectively,
wherein the second substrate includes a plurality of second insulating layers, a plurality of second wiring layers disposed on or in the plurality of second insulating layers, respectively, and a plurality of f second via layers penetrating at least one of the plurality of second insulating layers, respectively,
wherein at least one of the plurality of first insulating layers includes an organic material,
wherein at least one of the plurality of second insulating layers includes an organic material,
wherein at least one of the plurality of first wiring layers includes the first antenna pattern, and
wherein at least one of the plurality of second wiring layers includes the second antenna pattern.

21. The printed circuit board of claim 20,
wherein, among the plurality of first via layers, a first via layer disposed on an uppermost side includes a first connection via connected to the metal layer,
wherein, among the plurality of second via layers, a second via layer disposed on a lowermost side includes a second connection via connected to the metal layer, and
wherein the first and second connection vias are tapered in opposite directions.

22. The printed circuit board of claim 21,
wherein a width of an upper end of the first connection via is greater than a width of a lower end of the first connection via in a cross-section, and
wherein a width of a lower end of the second connection via is greater than a width of an upper end of the second connection via in the cross-section.

23. The printed circuit board of claim 1, further comprising:
a semiconductor chip mounted on a lower side of the first substrate,
wherein the semiconductor chip includes a radio frequency integrated circuit (RFIC).

24. A printed circuit board, comprising:
a first substrate including a first antenna pattern;
a second substrate disposed on the first substrate and including a second antenna pattern;
a metal layer disposed between the first and second substrates; and
a bonding layer disposed between the first and second substrates,
wherein at least one of the first and second substrates has a cavity having at least a portion disposed between the first and second antenna patterns, and
wherein at least a portion of a side surface of the metal layer has a step difference.

25. The printed circuit board of claim 24, further comprising:
a heterogeneous metal layer disposed in the metal layer,
wherein the heterogeneous metal layer includes a metal different from the metal layer.

26. The printed circuit board of claim 24,
wherein the bonding layer is disposed adjacent to the metal layer, and
wherein, in a region not overlapping the cavity in a plane, a thickness of the bonding layer is substantially the same as a thickness of the metal layer.

27. The printed circuit board of claim 24,
wherein each of the first and second substrates includes an organic material, and
wherein the bonding layer includes an inorganic material.

28. The printed circuit board of claim 24, wherein the metal layer includes nano-twinned copper.

29. A method of manufacturing a printed circuit board, the method comprising:
preparing a first substrate including a first antenna pattern and including a first metal layer formed on an outermost side thereof;
forming a first inorganic insulating film covering at least a portion of the first metal layer on the outermost side of the first substrate;
preparing a second substrate including a second antenna pattern and including a second metal layer formed on an outermost side thereof;
forming a second inorganic insulating film covering at least a portion of the second metal layer on the outermost side of the second substrate;
forming a cavity in at least one of the first and second substrates; and
bonding the first and second substrates to each other such that the first and second inorganic insulating films are bonded to each other and the first and second metal layers are bonded to each other,
wherein each of the first and second substrates includes an organic material.

30. The method of claim 29, wherein, in the forming the cavity, the cavity penetrates the second inorganic insulating film and further penetrates a portion of the second substrate.

31. The method of claim 29, further comprising:
exposing a surface of the first metal layer by planarizing the first metal layer and the first inorganic insulating film after the forming the first inorganic insulating film; and
exposing a surface of the second metal layer by planarizing the second metal layer and the second inorganic insulating film after the forming the second inorganic insulating film.

32. The method of claim 31,
wherein the bonding the first and second substrate to each other includes:
allowing the first and second inorganic insulating film to be in contact with each other and allowing the first and second metal layers to be in contact with each other,
bonding the first and second inorganic insulating films to each other at a first temperature, and
bonding the first and second metal layers to each other at a second temperature,
wherein the second temperature is higher than the first temperature.

33. The method of claim 31, wherein the bonding the first and second substrate to each other includes:
applying a metal paste including a metal different from the first and second metal layers between the first and second metal layers,
allowing the first and second inorganic insulating film to be in contact with each other and allowing the first and second metal layers to be in contact with the metal paste,
bonding the first and second inorganic insulating films to each other at a first temperature, and
bonding the first and second metal layers through the metal paste to each other at a second temperature,
wherein the second temperature is higher than the first temperature.

34. The method of claim 29,
wherein, in the preparing the first substrate and the preparing the second substrate,
the first substrate includes a plurality of first insulating layers, a plurality of first wiring layers disposed on or in the plurality of first insulating layers, respectively, and a plurality of first via layers penetrating at least one of the plurality of first insulating layers, respectively,
the second substrate includes a plurality of second insulating layers, a plurality of second wiring layers disposed on or in the plurality of second insulating layers, respectively, and a plurality of second via layers penetrating at least one of the plurality of second insulating layers, respectively,
at least one of the plurality of first insulating layers includes an organic material,
at least one of the plurality of second insulating layers includes an organic material,
at least one of the plurality of first wiring layers includes the first antenna pattern,
at least one of the plurality of second wiring layers includes the second antenna pattern,
among the plurality of first wiring layers, the first wiring layer disposed on an uppermost side includes the first metal layer, and
among the plurality of second wiring layers, the second wiring layer disposed on a lowermost side includes the second metal layer.

35. A printed circuit board, comprising:
a first substrate including a first antenna pattern;
a second substrate disposed on a first substrate and including a second antenna pattern;
a metal layer disposed between the first and second substrates; and
a bonding layer disposed between the first and second substrates and covering side surfaces of the metal layer,
wherein at least one of the first and second substrates has a cavity having at least a portion disposed between the first and second antenna patterns, and
wherein a thickness of the bonding layer between the first substrate and the cavity is smaller than a thickness of the bonding layer between the first and second substrates.

36. The printed circuit board of claim 35, wherein the metal layer includes a first metal layer disposed on an uppermost side of the first substrate and a second metal layer disposed on a lowermost side of the second substrate.

37. The printed circuit board of claim 36, wherein an upper surface of the first metal layer and a lower surface of the second metal layer are directly bonded to each other.

38. The printed circuit board of claim 36, wherein the metal layer includes a third metal layer disposed between the first and second metal layers and including a metal different from that of the first and second metal layers.

39. The printed circuit board of claim 35, wherein the bonding layer includes SiO₂, SiN or SiCN.

40. The printed circuit board of claim 35, wherein at least a portion of the cavity is filled with air.

41. A printed circuit board, comprising:
a first substrate including a plurality of first insulating layers, a plurality of first wiring layers disposed on or in the plurality of first insulating layers, one of the plurality of first wiring layers including a first antenna pattern;
a second substrate disposed on the first substrate and including a plurality of second insulating layers, a plurality of second wiring layers disposed on or in the plurality of second insulating layers, respectively, and a plurality of second via layers penetrating at least one of the plurality of second insulating layers, respectively, one of the plurality of second insulating layers including a second antenna pattern;
a metal layer disposed between the first and second substrates; and
a bonding layer disposed between the first and second substrates and covering side surfaces of the metal layer,
wherein at least one of the first and second substrates has a cavity having at least a portion disposed between the first and second antenna patterns, and
wherein a via layer among the plurality of first via layers which is connected to the metal layer and a via layer of the plurality of second via layers which is connected to the metal layer are tapered in opposite directions.

42. The printed circuit board of claim 41, wherein the metal layer includes a first metal layer disposed on an uppermost side of the first substrate and a second metal layer disposed on a lowermost side of the second substrate.

43. The printed circuit board of claim 42, wherein an upper surface of the first metal layer and a lower surface of the second metal layer are directly bonded to each other.

44. The printed circuit board of claim 42, wherein the metal layer includes a third metal layer disposed between the first and second metal layers and including a metal different from that of the first and second metal layers.

45. The printed circuit board of claim 41, wherein the bonding layer includes SiO₂, SiN or SiCN.

46. The printed circuit board of claim 41, wherein at least a portion of the cavity is filled with air.

47. The printed circuit board of claim 41, wherein the cavity is spaced apart from the plurality of first wiring layers and the plurality of second wiring layers.
